(19) United States
(12) Patent Application Publication
(10) Pub. No.: US 2009/0101401 A1
(43) Pub. Date: Apr. 23, 2009

(54) WIRING BOARD

(75) Inventors: Kazuhiro KOBAYASHI, Nagano-shi (JP); Takaharu Miyamoto, Nagano-shi (JP)

Correspondence Address: DRINKER BIDDLE & REATH (DC), 1500 K STREET, N.W., SUITE 1100, WASHINGTON, DC, 20005-1209, US

(73) Assignee: SHINKO ELECTRIC INDUSTRIES CO., LTD., NAGANO-SHI (JP)

(21) Appl. No.: 12/249,245

(22) Filed: Oct. 10, 2008

(30) Foreign Application Priority Data
Oct. 12, 2007 (JP) 2007-266169
Sep. 26, 2008 (JP) 2008-247687

(51) Int. Cl. H05K 1/11

(52) U.S. Cl. 174/261

(57) ABSTRACT

A thickness of the portion, which is placed between an electronic component mounting pad and a first wiring, of a first insulating layer (insulating layer in which electronic component mounting pads are placed) is set to be smaller than a thickness of the portion, which is placed between the first wiring and a second wiring, of a second insulating layer.

### TECHNICAL FIELD

The present disclosure relates to a wiring board and more particularly to a wiring board whose size in a thickness direction can be miniaturized and whose cost can be reduced.

### RELATED ART

Hitherto, a wiring board called coreless board has been available as a wiring board whose size in the thickness direction is miniaturized. The coreless board, which does not have a core board, has low strength as compared with a buildup wiring board with a core board (wiring board formed with a buildup structure on both sides of core board) and thus warpage easily occurs. A wiring board 200 as shown in FIG. 1 is available as a wiring board for making it possible to decrease warpage of the coreless board.

FIG. 1 is a sectional view of a wiring board in a related art.

Referring to FIG. 1, the wiring board 200 in the related art has solder resist layers 201 and 215, pads 202, resin layers 203 and 211, vias 204, 208, and 212, wiring 205 and 209, a reinforcing insulating layer 207, and electronic component mounting pads 213.

The solder resist layer 201 has a through part 218 (which passes through the solder resist layer 201) for placing the pad 202. The pad 202 has a connection face 202A where an external connection terminal 261 is disposed. The pad 202 is provided in the through part 218 so that the connection face 202A of the pad 202 and a face 201A of the solder resist layer 201 become roughly flush with each other. The pad 202 is a pad electrically connected to a mount board 260 (for example, mother board) through the external connection terminal 261. For example, an Au/Ni deposition layer with an Au layer and an Ni layer deposited in order can be used as a material of the pad 202.

The resin layer 203 is provided so as to cover most of a face 201B of the solder resist layer 201 (face of the solder resist layer 201 on the opposite side to the face 201A) and a face 202B of the pad 202. The resin layer 203 has an opening 219 to expose a part of the face 202B of the pad 202.

The via 204 is provided in the opening 219. The via 204 is formed integrally with the wiring 205 and has a lower end connected to the pad 202. The wiring 205 is provided on a face 203A of the resin layer 203. The wiring 205 is connected to an upper end of the via 204. For example, Cu can be used as a material of the via 204 and the wiring 205.

The reinforcing resin layer 207 is provided on the face 203A of the resin layer 203 so as to cover most of the wiring 205. The reinforcing resin layer 207 is provided by impregnating glass cloth of a reinforcing member with a resin. Thus, the reinforcing resin layer 207 has a thickness thicker than other resin layers 203 and 211 (for example, having a thickness of 35 μm). The thickness of the reinforcing resin layer 207 can be set to 50 μm to 100 μm. The reinforcing resin layer 207 has openings 221 to expose a part of the wiring 205. The openings 221 are formed by laser beam machining.

The via 208 is provided in the opening 221. The via 208 is formed integrally with the wiring 209 and has a lower end connected to the wiring 205. The wiring 209 is provided on a face 207A of the reinforcing resin layer 207. The wiring 209 is connected to an upper end of the via 208. For example, Cu can be used as a material of the via 208 and the wiring 209.

The resin layer 211 is provided on the face 207A of the reinforcing resin layer 207 so as to cover most of the wiring 209. The resin layer 211 has an opening 223 to expose a part of the wiring 209.

The via 212 is provided in the opening 223. The via 212 is formed integrally with the electronic component mounting pad 213 and has a lower end connected to the wiring 209. The electronic component mounting pad 213 is provided on a face 211A of the resin layer 211. The electronic component mounting pad 213 has a connection face 213A where an electronic component 250 (for example, semiconductor chip, chip capacitor, etc.,) is mounted. For example, Cu can be used as a material of the via 212 and the electronic component mounting pad 213.

The solder resist layer 215 has an opening 225 to expose the connection face 213A. The solder resist layer 215 is provided so as to cover the face 211A of the resin layer 211.

The described wiring board 200 has the reinforcing resin layer 207 provided by impregnating glass cloth of a reinforcing member with a resin and thus is enhanced in the strength and warpage of the wiring board 200 caused by the thermal expansion coefficient difference among the resin layers 203 and 211, the vias 204, 208, and 212, and the wiring 205 and 209 can be decreased. (For example, refer to patent document 1.)

[Patent document 1] Japanese Patent Laid-Open No. 2007-96260

However, the wiring board 200 in the related art is provided with the reinforcing resin layer 207 having a thickness thicker than the resin layer 203, 211 (for example, the thickness of the reinforcing resin layer 207 is 50 μm to 100 μm) for decreasing warpage of the wiring board 200 caused by the thermal expansion coefficient difference among the resin layers 203 and 211, the vias 204, 208, and 212, and the wiring 205 and 209 and therefore the size of the wiring board 200 in the thickness direction thereof becomes large; this is a problem.

Since the reinforcing resin layer 207 provided by impregnating glass cloth with a resin is expensive, there is a problem of an increase in the cost of the wiring board 200.

Further, to make the opening 221 in the reinforcing resin layer 207, it takes a time for a laser to pass through the glass cloth and thus there is a problem of an increase in the manufacturing cost of the wiring board 200.

### SUMMARY

Exemplary embodiments of the present invention provide a circuit board whose size in a thickness direction can be miniaturized, whose warpage can be decreased, and whose cost can be reduced.

According to one aspect of the invention, there is provided a wiring board comprising:

a first insulating layer;

an electronic component mounting pad having a connection face to which an electronic component is connected, the electronic component mounting pad being provided in the first insulating layer so that the connection face is exposed;

a via passing through a portion, which is opposed to the electronic component mounting pad, of the first insulating layer, the via having one end connected to the electronic component mounting pad;

a first wiring being provided on the first insulating layer and connected to an opposite end of the via;

a second insulating layer deposited on the first insulating layer, and

a second wiring being provided on the second insulating layer and electrically connected to the first wiring,

wherein a thickness of a portion, which is placed between the electronic component mounting pad and the first wiring, of the first insulating layer is smaller than a thickness of a portion, which is placed between the first wiring and the second wiring, of the second insulating layer.

According to another aspect of the invention, there is provided a wiring board comprising:

a first insulating layer;

an electronic component mounting pad having a connection face to which an electronic component is connected, the electronic component mounting pad being provided on the first insulating layer;

a via passing through a portion, which corresponds to the electronic component mounting pad, of the first insulating layer, the via having one end connected to the electronic component mounting pad;

a first wiring being provided on the first insulating layer and connected to an opposite end of the via;

a second insulating layer deposited on the first insulating layer, and

a second wiring being provided on the second insulating layer and electrically connected to the first wiring,

wherein a thickness of a portion, which is placed between the electronic component mounting pad and the first wiring, of the first insulating layer is smaller than a thickness of a portion, which is placed between the first wiring and the second wiring, of the second insulating layer.

According to the invention, the thickness of the portion, which is placed between the electronic component mounting pad and the first wiring, of the insulating layer (the portion, in which the insulating property between the electronic component mounting pad and the first wiring need not be secured, of the first insulating layer) is set to be smaller than the thickness of the portion, which is placed between the first wiring and the second wiring, of the second insulating layer (the portion, in which the insulating property between the first wiring and the second wiring needs to be secured, of the insulating layer). Therefore, the size of the wiring board in the thickness direction thereof can be miniaturized and warpage of the wiring board (warpage caused by the thermal expansion coefficient difference among the first wiring, the second wiring, the vias, and the first and second insulating layers) can be decreased.

It is made possible to decrease warpage of the wiring board without using a reinforcing resin layer provided by impregnating expensive glass cloth where an opening is hard to make with a resin. Therefore, the cost of the wiring board (containing the manufacturing cost thereof) can be reduced.

It is difficult on manufacturing to make the thickness of the portion, which is placed between the electronic component mounting pad and the first wiring, of the first insulating layer smaller than 5 μm. If the thickness of the portion, which is placed between the electronic component mounting pad and the first wiring, of the first insulating layer is made larger than the thickness of the portion, which is placed between the first wiring and the second wiring, of the second insulating layer, warpage of the wiring board cannot sufficiently be decreased.

According to the invention, the size of the wiring board in the thickness direction thereof can be miniaturized, warpage of the wiring board can be decreased, and the cost of the wiring board can be reduced.

Other features and advantages may be apparent from the following detailed description, the accompanying drawings and the claims.

### BRIEF DESCRIPTION OF THE DRAWINGS

In the accompanying drawings:

FIG. 1 is a sectional view of a wiring board in a related art;

FIG. 2 is a sectional view of a wiring board according to an embodiment of the invention;

FIG. 3A is a sectional view of a wiring board according to a first modified example of the embodiment of the invention;

FIG. 3B is a sectional view of a wiring board according to a second modified example of the embodiment of the invention;

FIG. 4 is a drawing to show a manufacturing process of a wiring board according to the embodiment of the invention (No. 1);

FIG. 5 is a drawing to show the manufacturing process of the wiring board according to the embodiment of the invention (No. 2);

FIG. 6 is a drawing to show the manufacturing process of the wiring board according to the embodiment of the invention (No. 3);

FIG. 7 is a drawing to show the manufacturing process of the wiring board according to the embodiment of the invention (No. 4);

FIG. 8 is a drawing to show the manufacturing process of the wiring board according to the embodiment of the invention (No. 5);

FIG. 9 is a drawing to show the manufacturing process of the wiring board according to the embodiment of the invention (No. 6);

FIG. 10 is a drawing to show the manufacturing process of the wiring board according to the embodiment of the invention (No. 7);

FIG. 11 is a drawing to show the manufacturing process of the wiring board according to the embodiment of the invention (No. 8); and

FIG. 12 is a drawing to show the manufacturing process of the wiring board according to the embodiment of the invention (No. 9); and

FIG. 13 is a graph to show a relationship between the thickness of the insulating layer and warpage of the wring board.

### DETAILED DESCRIPTION

Referring now to the accompanying drawings, there are shown embodiments of the invention.

### First Embodiment

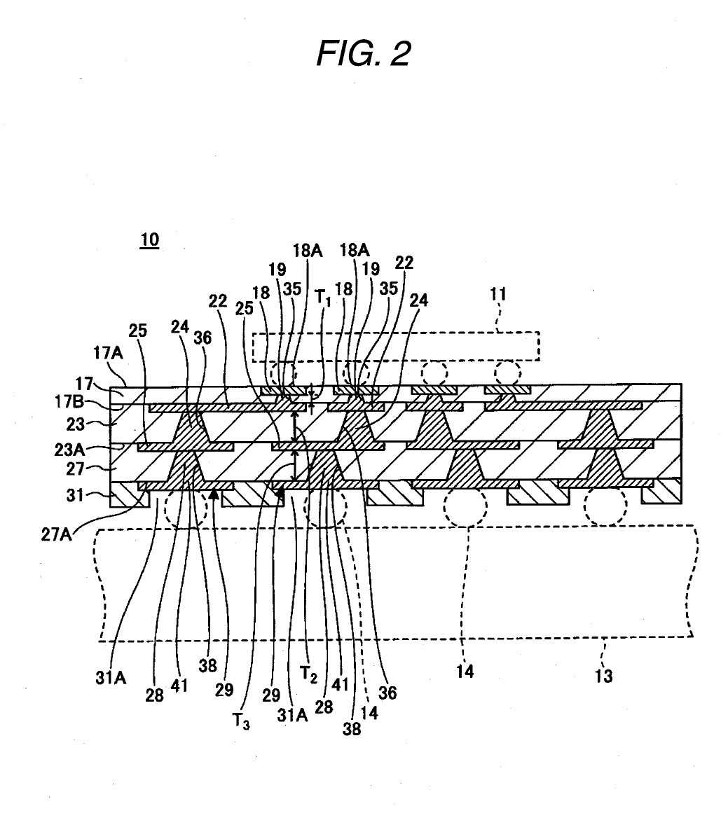

FIG. 2 is a sectional view of a wiring board according to an embodiment of the invention.

Referring to FIG. 2, a wiring board 10 of the embodiment is a coreless board and has an insulating layer 17 of a first insulating layer, electronic component mounting pads 18, vias 19, 24, and 28, wiring 22 of first wiring, insulating layers 23 and 27 of second insulating layers, wiring 25 and 29 of second wiring, and a solder resist layer 31.

The insulating layer 17 is an insulating layer for internally placing the electronic component mounting pads 18 on which an electronic component 11 is mounted and the vias 19, and disposing the wiring 22. A face 17A of the insulating layer 17 (face where the electronic component 11 is mounted) is made roughly flush with connection faces 18A of the electronic component mounting pads 18. The insulating layer 17 has openings 35 formed so as to pass through portions, which are opposed to the electronic component mounting pads 18, of the insulating layer 17. A thickness T₁ of the portion, which is placed between the electronic component mounting pad 18 and the wiring 22 provided on a face 17B of the insulating layer 17 (face positioned on the opposite side to the face 17A of the insulating layer 17), of the insulating layer 17 is formed so as to become smaller than a thickness T₂ of the portion, which is placed between the wiring 22 and the wiring 25, of the insulating layer 23 and smaller than a thickness T₃ of the portion, which is placed between the wiring 25 and the wiring 29, of the insulating layer 27.

The thickness T₁ of the portion, which is placed between the electronic component mounting pad 18 and the wiring 22 provided on the face 17B of the insulating layer 17 (face positioned on the opposite side to the face 17A of the insulating layer 17), of the insulating layer 17 is thus formed so as to become smaller than the thickness T₂ of the portion, which is placed between the wiring 22 and the wiring 25, of the insulating layer 23 and smaller than the thickness T₃ of the portion, which is placed between the wiring 25 and the wiring 29, of the insulating layer 27. Therefore, the size of the wiring board 10 in the thickness direction thereof can be miniaturized and warpage of the wiring board 10 (warpage caused by the thermal expansion coefficient difference among the vias 19, 24, and 28, the wiring 22, 25, and 29, and the insulating layers 23 and 27) can be decreased. It is technically difficult on manufacturing to make the thickness T₁ of the insulating layer 17 smaller than 5 μm. If the thickness T₁ of the insulating layer 17 is made larger than the thickness T₂ of the insulating layer 23 and the thickness T₃ of the insulating layer 27, warpage of the wiring board 10 cannot sufficiently be decreased.

Since the electronic component mounting pad 18 and the wiring 22 are connected by the via 19, if the thickness T₁ of the insulating layer 17 is reduced, the electrical characteristic of the wiring board 10 is scarcely affected. If wiring routed on the face 17A of the insulating layer 17 is formed on the face 17A, it is difficult to reduce the thickness T₁ of the insulating layer 17 from the viewpoints of preventing a short circuit with the wiring 22 formed on the face 17B of the insulating layer 17 and design considering the electrical characteristic. In the wiring board 10 of the embodiment, however, only the electronic component mounting pads 18 are provided on the face 17A of the insulating layer 17 and are connected directly to the portions, which are placed just below the electronic component mounting pads 18, of the wiring 22 by the vias 19. Therefore, it is not necessary to provide wiring routed on the face 17A of the insulating layer 17 to connect the electronic component mounting pads 18 and the wiring 22. Thus, in the wiring board 10 of the embodiment, if the thickness T₁ of the insulating layer 17 is reduced, a problem relating to a short circuit or the electrical characteristic does not occur. Therefore, to take measures against warpage, the thickness T₁ of the insulating layer 17 can be adjusted appropriately.

It is preferable that one electronic component mounting pad 18 and the wiring 22 connected to the other electronic component mounting pad 18 are formed in a state that they are not overlapped with each other when they are viewed from the above. From such a structure, the insulating property between one electronic component mounting pad 18 and the wiring 22 connected to the other electronic component mounting pad 18 can be secured even if the thickness T₁ of the insulating layer 17 is reduced.

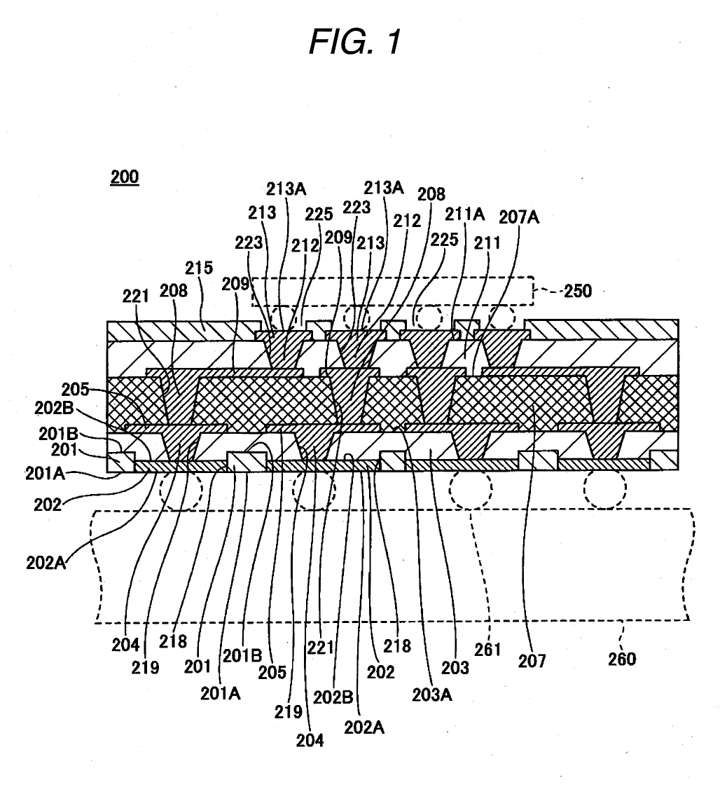

It is made possible to decrease warpage of the wiring board 10 without providing the reinforcing resin layer 207 (see FIG. 1) expensive and hard to work, provided in the wiring board 200 to decrease warpage of the wiring board 200 in the related art, so that the cost of the wiring board 10 (containing the manufacturing cost thereof) can be reduced. For example, a resin layer made of an insulating resin of epoxy resin, polyimide resin, etc., can be used as the insulating layer 17.

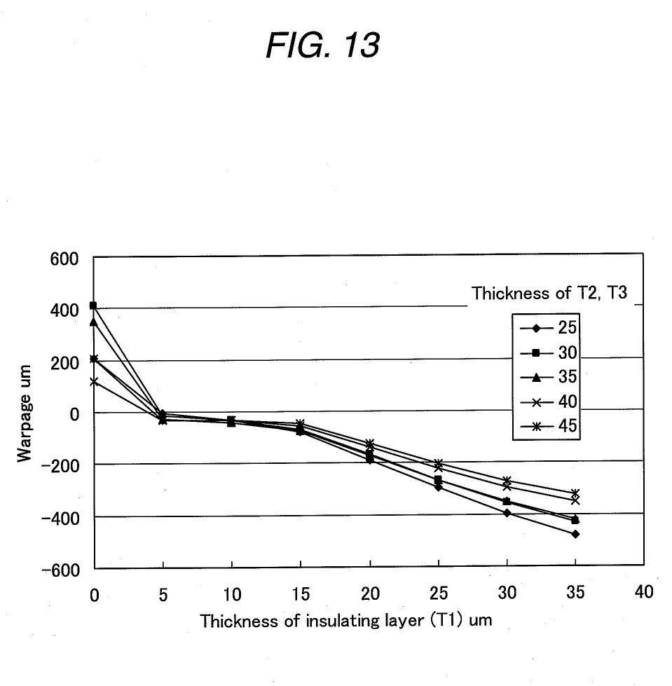

The warpage amount simulation results of the wiring board 10 with the thickness T₂, T₃ of the insulating layer 23, 27 set to 25 μm, 30 μm, 35 μm, 40 μm, 45 μm and the thickness T₁ of the insulating layer 17 set to 0 μm, 5 μm, 10 μm, 15 μm, 20 μm, 25 μm, 30 μm, and 35 μm will be discussed. Table 1 shows a relationship between the thickness T₁ of the insulating layer 17 and warpage of the wring board. FIG. 13 shows a relationship between the thickness T₁ of the insulating layer 17 and warpage of the wring board in a chart.

TABLE 1

| | | thickness T₂ andT₃ | | | | |
|---|---|---|---|---|---|---|
| | | 25 | 30 | 35 | 40 | 45 |
| thickness | 0 | 210 | 410 | 350 | 210 | 120 |
| T₁ | 5 | −6 | −16 | −27 | −30 | −34 |
| | 10 | −32 | −33 | −41 | −32 | −31 |
| | 15 | −79 | −70 | −75 | −55 | −48 |
| | 20 | −188 | −168 | −170 | −138 | −126 |
| | 25 | −297 | −267 | −266 | −222 | −204 |
| | 30 | −398 | −357 | −352 | −296 | −272 |
| | 35 | −480 | −427 | −419 | −350 | −321 |

(Unit: μm)

The simulation was performed in a condition that material of the wiring is copper and material of the insulating layer (insulating layers 17, 23, 27) is epoxy resin, and the thickness T₂, T₃ of the insulating layer 23, 27 is set to 25 μm, 30 μm, 35 μm, 40 μm, 45 μm and the thickness T₁ of the insulating layer 17 is set to 0 μm, μm, 10 μm, 15 μm, 20 μm, 25 μm, 30 μm, and 35 μm.

In Table 1, the warpage amount of the wiring board when the warpage does not occur is zero, and the concave-shaped warpage is indicated by the negative number while the convex-shaped warpage is indicated by the positive number. The thickness T₁ of 0 μm indicates a case where the insulating layer 17 is not provided (a case where the electronic component mounting pad 18 is a part of the wiring 22).

From the results, it can be acknowledged that if the allowable range of warpage of the wiring board 10 is set to 200 μm or less (absolute value), the thickness T₁ of the insulating layer 17 can be selected as required in the range of 5 μm to 20 μm. It is technically difficult on manufacturing to make the thickness T₁ of the insulating layer 17 smaller than 5 μm. If the thickness T₁ of the insulating layer 17 is made larger than 20 μm, the allowable range of warpage of the wiring board 10, 200 μm, is exceeded.

However, in view of mounting the electronic component on the wiring board or mounting the wiring board on the mother board, the warpage amount of the wiring board 10 is preferably 80 μm or less (absolute value). Therefore, it can be acknowledged that if the allowable range of warpage of the wiring board 10 is set to 80 μm or less, the thickness T₁ of the insulating layer 17 can be selected as required in the range of 5 μm to 15 μm.

Further, it can be acknowledged that the thickness T₂, T₃ of the insulating layer 23, 27 is preferably set to 25 μm to 45 μm. Considering the insulating property in addition to warpage of the wiring board or miniaturized thickness direction of the wiring board, the thickness T₂, T₃ of the insulating layer 23, 27 is more preferably set to 30 μm to 40 μm.

Although the warpage amount simulation results of the wiring board has been described above, the wiring board which was actually made also showed the warpage decreasing effect corresponding to the simulation results.

Each electronic component mounting pad 18 has a connection face 18A where the electronic component 11 is mounted (connected). The electronic component mounting pad 18 is internally placed in the insulating layer 17 so that the connection face 18A and the face 17A of the insulating layer 17 become roughly flush with each other. For example, an Au/Pd/Ni deposition film with an Au layer (for example, 0.05 μm in thickness), a Pd layer (for example, 0.05 μm in thickness), and an Ni layer (for example, 5 μm in thickness) deposited in order from the connection face 18A side can be used as the electronic component mounting pad 18. In this case, the electronic component 11 is mounted on the Au layer.

The via 19 is provided in the opening 35 formed in the insulating layer 17. It has one end connected to the electronic component mounting pad 18. The via 19 is formed integrally with the wiring 22 for electrically connecting the electronic component mounting pad 18 and the wiring 22.

The wiring 22 is provided on the face 17B of the insulating layer 17 (face of the insulating layer 17 positioned on the opposite side to the face 17A). The wiring 22 is formed integrally with the via 19. For example, the via 19 and the wiring 22 can be formed according to a semi-additive process. For example, Cu can be used as a material of the via 19 and the wiring 22.

The insulating layer 23 is provided on the face 17B of the insulating layer 17 so as to cover most of the wiring 22. The insulating layer 23 is an insulating layer for internally placing the vias 24 and forming the wiring 25. The insulating layer 23 has openings 36 to expose a part of the wiring 22. The opening 36 is provided for disposing the via 24. The wiring 25 is disposed on a face 23A of the insulating layer 23 (face of the insulating layer 23 on the opposite side to the side coming in contact with the insulating layer 17). Since the insulating property between the wiring 22 and the wiring 25 needs to be secured, the thickness T₂ of the portion, which is placed between the wiring 22 and the wiring 25, of the insulating layer 23 is formed so as to become larger than the thickness T₁ of the insulating layer 17. Specifically, the thickness T₂ of the portion, which is placed between the wiring 22 and the wiring 25, of the insulating layer 23 can be set to 25 μm to 45 μm, for example. For example, a resin layer made of an insulating resin of epoxy resin, polyimide resin, etc., can be used as the insulating layer 23.

The via 24 is provided in the opening 36 formed in the insulating layer 23. It has one end connected to the wiring 22. The via 24 is formed integrally with the wiring 25 provided on the face 23A of the insulating layer 23 for electrically connecting the wiring 22 and the wiring 25.

The wiring 25 is provided on the face 23A of the insulating layer 23 (face of the insulating layer 23 on the opposite side to the side coming in contact with the insulating layer 17). The wiring 25 is formed integrally with the via 24. For example, the via 24 and the wiring 25 can be formed according to a semi-additive process. For example, Cu can be used as a material of the via 24 and the wiring 25.

The insulating layer 27 is provided on the face 23A of the insulating layer 23 so as to cover most of the wiring 25. The insulating layer 27 is an insulating layer for internally placing the vias 28 and forming the wiring 29. The insulating layer 27 has openings 38 to expose a part of the wiring 25. The opening 38 is provided for disposing the via 28. The wiring 29 is disposed on a face 27A of the insulating layer 27 (face of the insulating layer 27 on the opposite side to the side coming in contact with the insulating layer 23). Since the insulating property between the wiring 25 and the wiring 29 needs to be secured, the thickness T₃ of the portion, which is placed between the wiring 25 and the wiring 29, of the insulating layer 27 is formed so as to become larger than the thickness T₁ of the insulating layer 17. Specifically, the thickness T₃ of the portion, which is placed between the wiring 25 and the wiring 29, of the insulating layer 27 can be set to 25 μm to 45 μm, for example. For example, a resin layer made of an insulating resin of epoxy resin, polyimide resin, etc., can be used as the insulating layer 27.

The via 28 is provided in the opening 38 formed in the insulating layer 27. It has one end connected to the wiring 25. The via 28 is formed integrally with the wiring 29 provided on the face 27A of the insulating layer 27 for electrically connecting the wiring 25 and the wiring 29.

The wiring 29 is provided on the face 27A of the insulating layer 27 (face of the insulating layer 27 on the opposite side to the side coming in contact with the insulating layer 23). It is placed so as to face a part of the wiring 25 through the insulating layer 27. The wiring 29 is formed integrally with the via 28. The wiring 29 has pad parts 41 where external connection terminals 14 (for example, solder balls) are disposed. The pad part 41 is a part electrically connected to a mount board 13 of a mother board, etc., through the external connection terminal 14. The wiring 29 is formed integrally with the via 28. For example, the via 28 and the wiring 29 can be formed according to a semi-additive process. For example, Cu can be used as a material of the via 28 and the wiring 29.

In drawings, it is shown that only the pad part 41 is provided on the face 27A of the insulating layer 27; however, other portion of the wiring 29 (the portion of the wiring 29 other than pad part 41) is actually also formed on the face 27A of the insulating layer 27. Further, the diameter of the electronic component mounting pad 18 is, for example, in a range of 50 to 150 μm while the diameter of the pad part 41 for the external connection terminal is, for example, in a range of 200 to 1000 μm. Therefore, it is shown in drawings that one pad part 41 and the wiring 25 connected to the other pad part 41 are not overlapped with each other when they are viewed from the above; however, one pad part 41 and the wiring 25 connected to the other pad part 41 are actually overlapped with each other when they are viewed from the above. From this fact, it is not possible to make the thickness T₃ of the insulating layer 27 small in order to secure the insulating property between the wiring 29 including pad parts 41 formed on the face 27A of the insulating layer 27 and the wiring 25.

The solder resist layer 31 is provided on the face 27A of the insulating layer 27 so as to cover the wiring 29 of the portion except the pad parts 41. The solder resist layer 31 has openings 31A to expose the pad parts 41.

According to the wiring board of the embodiment, the thickness T₁ of the portion, which is placed between the electronic component mounting pad 18 and the wiring 22, of the insulating layer 17 (the portion, in which the insulating property between the electronic component mounting pad 18 and the wiring 22 need not be secured, of the insulating layer 17) is set to be smaller than the thickness T₂ of the portion, which is placed between the wiring 22 and the wiring 25, of the insulating layer 23 (the portion, in which the insulating property between the wiring 22 and the wiring 25 needs to be secured, of the insulating layer) and is set to be smaller than the thickness T₃ of the portion, which is placed between the wiring 25 and the wiring 29 opposed to each other with one insulating layer 27 between, of the insulating layer 27 (the portion, in which the insulating property between the wiring 25 and the wiring 29 needs to be secured, of the insulating layer). Therefore, the size of the wiring board 10 in the thickness direction thereof can be miniaturized and warpage of the wiring board 10 can be decreased.

It is made possible to decrease warpage of the wiring board 10 without using the reinforcing resin layer 207 (see FIG. 1) provided by impregnating expensive glass cloth where an opening is hard to make with a resin, so that the cost of the wiring board 10 (containing the manufacturing cost thereof) can be reduced.

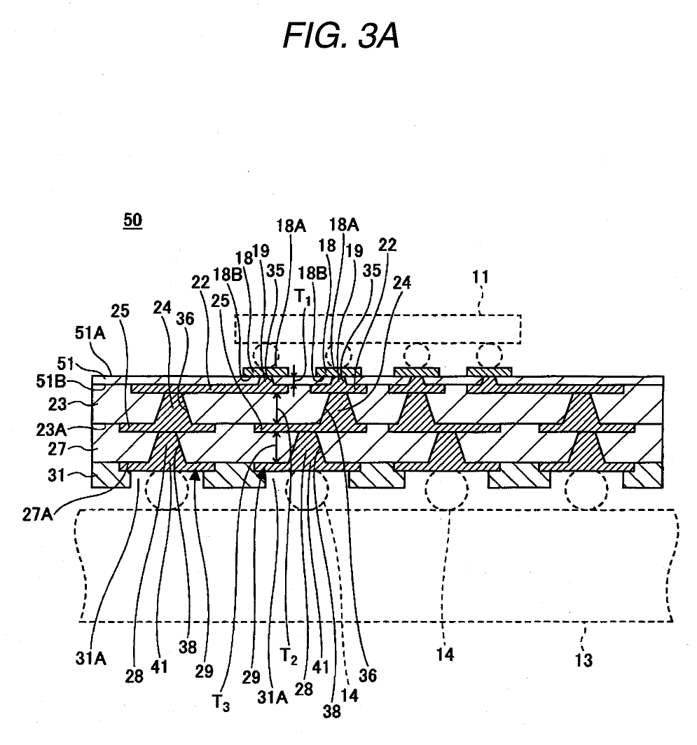

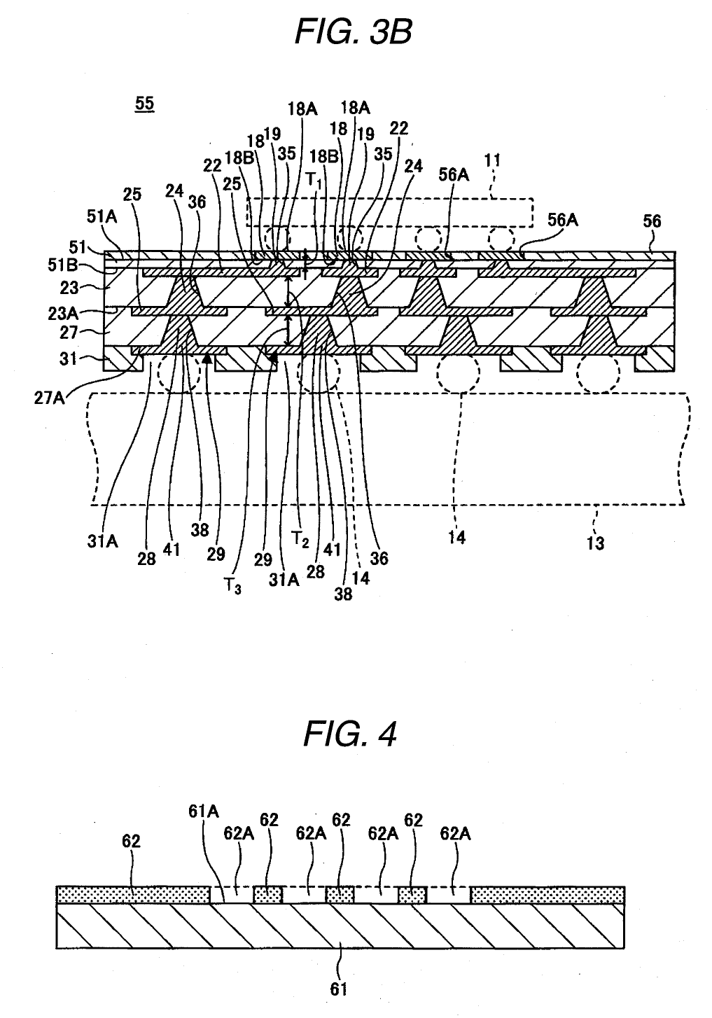

FIG. 3A is a sectional view of a wiring board according to a first modified example of the embodiment of the invention. Components identical with those of the wiring board 10 shown in FIG. 2 are denoted by the same reference numerals in FIG. 3A.

Referring to FIG. 3A, a wiring board 50 of the first modified example of the embodiment is the same as the wiring board 10 except that an insulating layer 51 is provided in place of the insulating layer 17 provided in the wiring board 10 of the embodiment.

The insulating layer 51 is formed like the insulating layer 17 except the portion, which is placed from the connection face 18A to a face 18B of the electronic component mounting pad 18 positioned on the opposite side to the connection face 18A, of the insulating layer 17 provided in the wiring board 10. A face 51A of the insulating layer 51 is made roughly flush with the connection face 18B of the electronic component mounting pad 18. Wiring 22 and an insulating layer 23 are provided on a face 51B of the insulating layer 51 (face of the insulating layer 51 placed on the opposite side to the face 51A).

The described wiring board 50 can provide similar advantages to those of the wiring board 10 previously described.

FIG. 3B is a sectional view of a wiring board according to a second modified example of the embodiment of the invention. Components identical with those of the wiring board 50 shown in FIG. 3A are denoted by the same reference numerals in FIG. 3B.

Referring to FIG. 3B, a wiring board 55 of the second modified example of the embodiment is the same as the wiring board 50 except that a solder resist layer 56 is further provided in the configuration of the wiring board 50 of the first modified example of the embodiment.

The solder resist layer 56 is provided on a face 51A of an insulating layer 51. It has openings 56A in which electronic component mounting pads 18 are housed. The solder resist layer 56 exposes connection faces 18A of the electronic component mounting pads 18. The thickness of the solder resist layer 56 is formed so as to roughly equal the thickness of the electronic component mounting pad 18. A resin layer made up of epoxy resin, polyimide resin, acrylic resin, etc., can be used as the solder resist layer 56. In the wiring board 55, the insulating layer 51 and the solder resist layer 56 correspond to a first insulating layer as claimed in Claims.

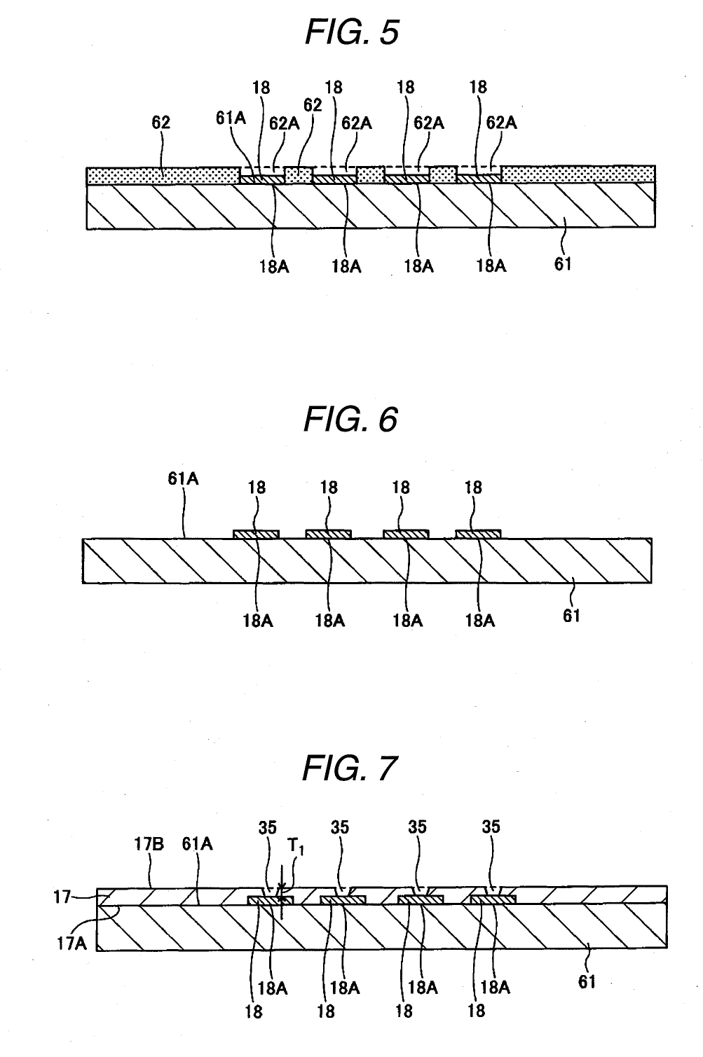

The described wiring board 55 can be manufactured by forming a solder resist layer 56 having openings 56A instead of a resist film 62 for plating and next forming electronic component mounting pads 18 in the openings 56A in the steps shown in FIGS. 4 and 5 described later and then performing similar steps to those shown in FIGS. 7 to 12 described later in a state in which the solder resist layer 56 is left.

FIGS. 4 to 12 are drawings to show a manufacturing process of a wiring board according to the embodiment of the invention. Components identical with those of the wiring board 10 of the embodiment are denoted by the same reference numerals in FIGS. 4 to 12.

A manufacturing method of the wiring board 10 of the embodiment will be discussed with reference to FIGS. 4 to 12. To begin with, in the step shown in FIG. 4, a resist film 62 for plating having openings 62A is formed on a face 61A of a substrate 61 having electric conductivity. At this time, the openings 62A are formed so as to expose the portions corresponding to formation regions of electronic component mounting pads 18 of the face 61A of the substrate 61. Specifically, the resist film 62 having the openings 62A is formed, for example, by applying a photosensitive resist and then exposing and developing the photosensitive resist. For example, a metal plate (for example, a Cu plate), metal foil (for example, Cu foil), etc., can be used as the substrate 61.

Next, in the step shown in FIG. 5, electronic component mounting pads 18 are formed on the portions exposed to the openings 62A of the substrate 61. Specifically, to use an Au/Pd/Ni deposition film as the electronic component mounting pads 18, for example, an Au layer (for example, 0.05 μm in thickness), a Pd layer (for example, 0.05 μm in thickness), and an Ni layer (for example, 5 μm in thickness) are deposited in order on the face 61A of the substrate 61 according to an electrolytic plating method with the substrate 61 as a feeding layer, thereby forming the electronic component mounting pads 18. As the electronic component mounting pads 18, an Au/Pd/Ni/Cu deposition film may be used in place of the Au/Pd/Ni deposition film.

Next, in the step shown in FIG. 6, the resist film 62 shown in FIG. 5 is removed. Next, in the step shown in FIG. 7, an insulating layer 17 having openings 35 each to expose a part of the electronic component mounting pad 18 is formed. For example, a resin layer made of an insulating resin of epoxy resin, polyimide resin, etc., can be used as the insulating layer 17. The insulating layer may be formed by depositing resin films made of epoxy resin, polyimide resin, etc., for example. The openings 35 can be formed by laser beam machining, for example.

A thickness T₁ of the portion, which is placed between the electronic component mounting pad 18 and wiring 22 provided on a face 17B of the insulating layer 17 (face positioned on the opposite side to a face 17A of the insulating layer 17), of the insulating layer 17 is formed so as to become smaller than a thickness T₂ of the portion, which is placed between the wiring 22 and wiring 25, of an insulating layer 23 and smaller than a thickness T₃ of the portion, which is placed between the wiring 25 and wiring 29, of an insulating layer 27.

The thickness T₁ of the portion, which is placed between the electronic component mounting pad 18 and the wiring 22 provided on the face 17B of the insulating layer 17 (face positioned on the opposite side to the face 17A of the insulating layer 17), of the insulating layer 17 is thus formed so as to become smaller than the thickness T₂ of the portion, which is placed between the wiring 22 and the wiring 25, of the insulating layer 23 and smaller than the thickness T₃ of the portion, which is placed between the wiring 25 and the wiring 29 of the insulating layer 27. Therefore, the size of the wiring board 10 in the thickness direction thereof can be miniaturized and warpage of the wiring board 10 (warpage caused by the thermal expansion coefficient difference among vias 19, 24, and 28, the wiring 22, 25, and 29, and the insulating layers 23 and 27) can be decreased. It is technically difficult on manufacturing to make the thickness T₁ of the insulating layer 17 smaller than 5 μm. If the thickness T₁ of the insulating layer 17 is made larger than the thickness T₂ of the insulating layer 23, the thickness T₃ of the insulating layer 27, warpage of the wiring board 10 cannot sufficiently be decreased.

Since the electronic component mounting pad 18 and the wiring 22 are connected by the via 19, if the thickness T₁ of the insulating layer 17 is reduced, the electrical characteristic of the wiring board 10 is scarcely affected. If wiring routed on the face 17A of the insulating layer 17 is formed on the face 17A, it is difficult to reduce the thickness T₁ of the insulating layer 17 from the viewpoints of preventing a short circuit with the wiring 22 formed on the face 17B of the insulating layer 17 and design considering the electrical characteristic. In the wiring board 10 of the embodiment, however, only the electronic component mounting pads 18 are provided on the face 17A of the insulating layer 17 and are connected directly to the portions, which are placed just below the electronic component mounting pads 18, of the wiring 22 by the vias 19. Therefore, it is not necessary to provide wiring routed on the face 17A of the insulating layer 17 to connect the electronic component mounting pads 18 and the wiring 22. Thus, in the wiring board 10 of the embodiment, if the thickness T₁ of the insulating layer 17 is reduced, a problem relating to a short circuit or the electrical characteristic does not occur. Therefore, to take measures against warpage, the thickness T₁ of the insulating layer 17 can be adjusted appropriately.

It is made possible to decrease warpage of the wiring board 10 without providing the reinforcing resin layer 207 (see FIG. 1) expensive and hard to work, provided in the wiring board 200 to decrease warpage of the wiring board 200 in the related art, so that the cost of the wiring board 10 (containing the manufacturing cost thereof) can be reduced.

If the allowable range of warpage of the wiring board 10 is set to 80 μm or less, the thickness T₁ of the insulating layer 17 can be selected as required in the range of 5 μm to 15 μm. It is technically difficult on manufacturing to make the thickness T₁ of the insulating layer 17 smaller than 5 μm. If the thickness T₁ of the insulating layer 17 is made larger than 15 μm, the allowable range of warpage of the wiring board 10, 80 μm, is exceeded.

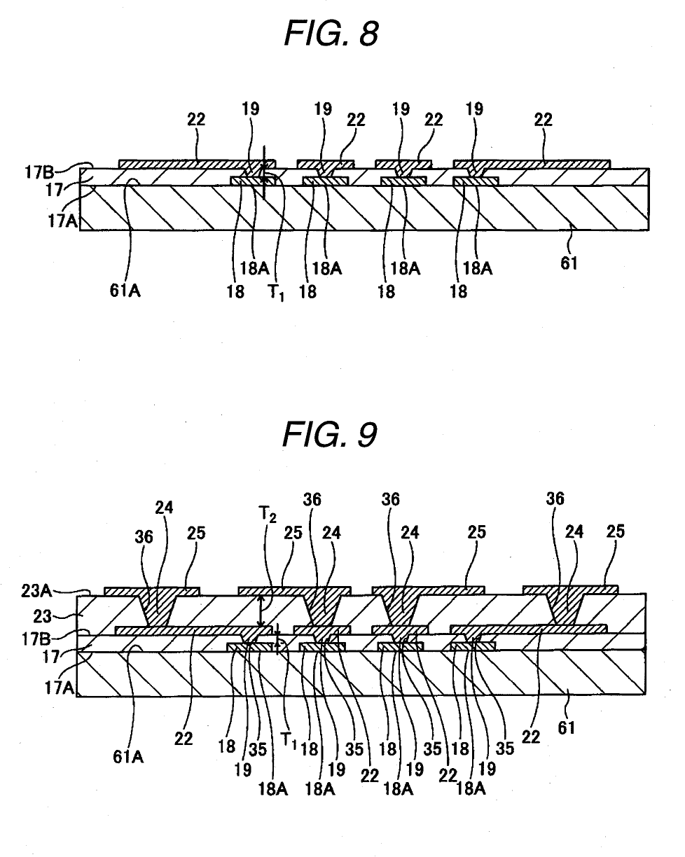

Next, in the step shown in FIG. 8, the vias 19 and the wiring 22 are formed at the same time. The vias 19 and the wiring 22 are formed according to a semi-additive process, for example. Specifically, a seed layer (for example, a Cu layer) is formed so as to cover the upper face side of a structure shown in FIG. 7 according to an electrolytic plating method and then a resist film (not shown) having openings (not shown) is formed in the portion corresponding to the formation region of the wiring 22 on the seed layer (not shown). Next, a plating film (for example, a Cu plating film) is grown by precipitation on the portions, which are exposed to the openings, of the seed layer according to the electrolytic plating method with the seed layer as a feeding layer and then the resist film is removed and next the seed layer not covered with the plating film is removed, thereby forming the vias 19 and the wiring 22 at the same time.

Next, in the step shown in FIG. 9, the insulating layer 23 having openings 36, the vias 24, and the wiring 25 are formed in order according to a similar technique to the steps previously described with reference to FIGS. 7 and 8. For example, a resin layer made of an insulating resin of epoxy resin, polyimide resin, etc., can be used as the insulating layer 23. The thickness T₂ of the portion, which is placed between the wiring 22 and the wiring 25, of the insulating layer 23 is formed so as to become larger than the thickness T₁ of the insulating layer 17. Specifically, the thickness T₂ of the insulating layer 23 can be set to 25 μm to 45 μm, for example. For example, Cu can be used as a material of the via 24 and the wiring 25.

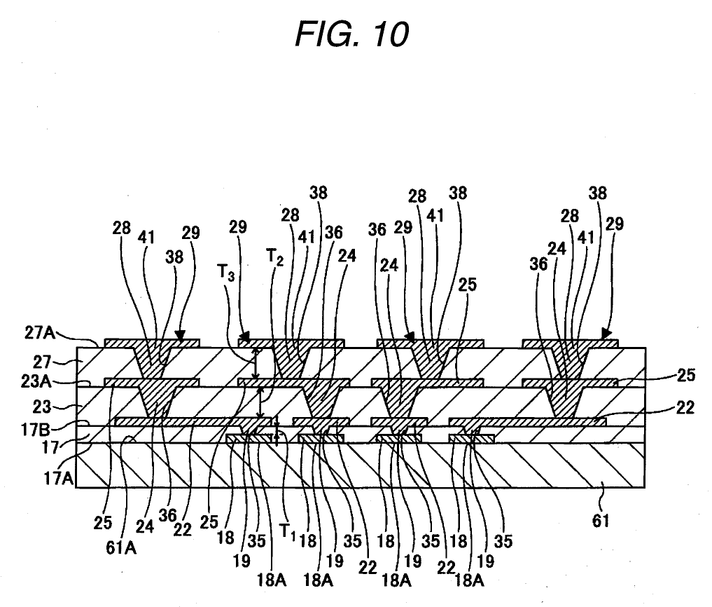

Next, in the step shown in FIG. 10, the insulating layer 27 having openings 38, the vias 28, and the wiring 29 are formed in order according to a similar technique to the steps previously described with reference to FIGS. 7 and 8. For example, a resin layer made of an insulating resin of epoxy resin, polyimide resin, etc., can be used as the insulating layer 27. The thickness T₃ of the portion, which is placed between the wiring 25 and the wiring 29, of the insulating layer 27 is formed so as to become larger than the thickness T₁ of the insulating layer 17. Specifically, the thickness T₃ of the insulating layer 27 can be set to 25 μm to 45 μm, for example. For example, Cu can be used as a material of the via 28 and the wiring 29.

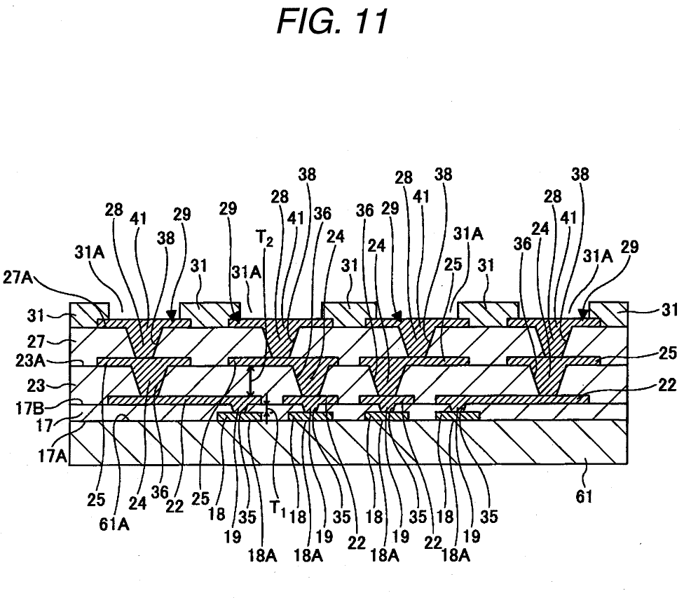

Next, in the step shown in FIG. 11, a solder resist layer 31 having openings 31A is formed on a face 27A of the insulating layer so as to cover the wiring 29 except pad parts 41. The openings 31A are formed so as to expose the pad parts 41.

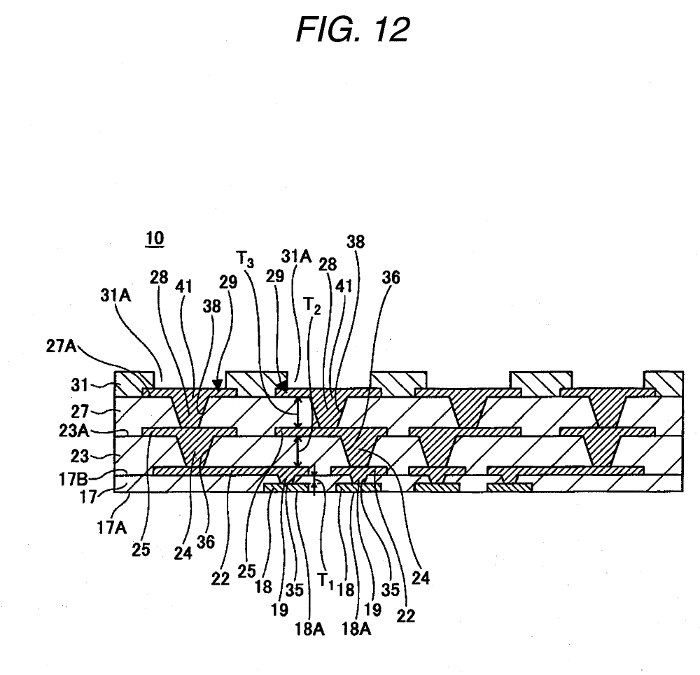

Next, in the step shown in FIG. 12, the substrate 61 shown in FIG. 11 is removed. Accordingly, the wiring board 10 is manufactured. In FIG. 12, the wiring board 10 shown in FIG. 2 is flipped vertically from top to bottom for the manufacturing process.

Although the preferred embodiment of the invention has been described in detail, it is to be understood that the invention is not limited to the specific embodiment and that various modifications and changes can be made without departing from the spirit and the scope of the invention as claimed.

For example, the wiring board 10, 50, 55 described above can also be used as a PGA (Pin Grid Array) having pins joined to the pad parts 41 and an LAG (Land Grid Array) using the pad parts 41 as external connection terminals as well as a BGA (Ball Grid Array).

The invention can be applied to a coreless board.

What is claimed is:

1. A wiring board comprising:
a first insulating layer;
an electronic component mounting pad having a connection face to which an electronic component is connected, the electronic component mounting pad being provided in the first insulating layer so that the connection face is exposed;
a via passing through a portion, which is opposed to the electronic component mounting pad, of the first insulating layer, the via having one end connected to the electronic component mounting pad;
a first wiring being provided on the first insulating layer and connected to an opposite end of the via;
a second insulating layer deposited on the first insulating layer, and
a second wiring being provided on the second insulating layer and electrically connected to the first wiring,
wherein a thickness of a portion, which is placed between the electronic component mounting pad and the first wiring, of the first insulating layer is smaller than a thickness of a portion, which is placed between the first wiring and the second wiring, of the second insulating layer.

2. The wiring board as claimed in claim 1 wherein the thickness of the portion, which is placed between the electronic component mounting pad and the first wiring, of the first insulating layer is 5 μm to 20 μm.

3. The wiring board as claimed in claim 1 wherein the first insulating layer is a resin layer.

4. The wiring board as claimed in claim 1 wherein the thickness of the portion, which is placed between the first wiring and the second wiring, of the second insulating layer is 25 μm to 45 μm.

5. A wiring board comprising:
a first insulating layer;
an electronic component mounting pad having a connection face to which an electronic component is connected, the electronic component mounting pad being provided on the first insulating layer;
a via passing through a portion, which corresponds to the electronic component mounting pad, of the first insulating layer, the via having one end connected to the electronic component mounting pad;
a first wiring being provided on the first insulating layer and connected to an opposite end of the via;
a second insulating layer deposited on the first insulating layer, and
a second wiring being provided on the second insulating layer and electrically connected to the first wiring,
wherein a thickness of a portion, which is placed between the electronic component mounting pad and the first wiring, of the first insulating layer is smaller than a thickness of a portion, which is placed between the first wiring and the second wiring, of the second insulating layer.

6. The wiring board as claimed in claim 5 wherein the thickness of the portion, which is placed between the electronic component mounting pad and the first wiring, of the first insulating layer is 5 μm to 20 μm.

7. The wiring board as claimed in claim 5 wherein the first insulating layer is a resin layer.

8. The wiring board as claimed in claim 5 wherein the thickness of the portion, which is placed between the first wiring and the second wiring, of the second insulating layer is 25 μm to 45 μm.
